(19) United States
(12) Patent Application Publication
(10) Pub. No.: US 2024/0389378 A1
(43) Pub. Date: Nov. 21, 2024

(54) SHORT WAVELENGTH INFRARED UP-CONVERSION DEVICE

(71) Applicant: UNIVERSITY-INDUSTRY COOPERATION GROUP OF KYUNG HEE UNIVERSITY, Yongin-si (KR)

(72) Inventors: Hyeonggeun YU, Seoul (KR); Min Chul SUH, Seoul (KR); Hae Jung SON, Seoul (KR); Ji Hun KIM, Changwon-si (KR); Jong Yun LEE, Seoul (KR)

(73) Assignee: UNIVERSITY-INDUSTRY COOPERATION GROUP OF KYUNG HEE UNIVERSITY, Yongin-si (KR)

(21) Appl. No.: 18/667,126

(22) Filed: May 17, 2024

(30) Foreign Application Priority Data
May 17, 2023 (KR) 10-2023-0063836

(51) Int. Cl. H10K 50/17; H10K 50/818; H10K 101/60; H10K 102/00; H10K 102/10

(52) U.S. Cl. CPC H10K 50/17; H10K 50/818; H10K 2101/60; H10K 2102/101; H10K 2102/351

(57) ABSTRACT

A short wavelength infrared up-conversion device of one embodiment includes a first electrode connected to an anode, an OLED layer stacked on the first electrode and up-converting short-wavelength infrared ray incident through the first electrode into visible light, a blocking layer located between the first electrode and an infrared-sensitive thin film layer to prevent hole injection into the infrared-sensitive thin film layer, an infrared-sensitive thin film layer located between the blocking layer and the OLED layer, and injecting holes into the OLED layer from electron-hole pairs created by absorbing the short-wavelength infrared ray incident through the first electrode, and a transparent second electrode stacked on the OLED layer and connected to a cathode, wherein the first electrode includes a transparent electrode unit, and a reflective electrode unit that reflects visible light incident from the OLED layer to the first electrode toward the second electrode.

### CROSS-REFERENCE TO RELATED APPLICATION

This application claims the benefit of Korea Patent Application No. 10-2023-0063836 filed on 17 May 2023, which are incorporated herein by reference for all purposes as if fully set forth herein.

### BACKGROUND OF THE INVENTION

### Field of the Invention

The present disclosure relates to a device that up-converts short wavelength infrared rays into visible light.

### Description of the Related Art

Shortwave infrared (SWIR) has the advantage of having less scattering in the atmosphere compared to near infrared (NIR) and being harmless to human eyes, so it has high utility value in military security, medical imaging, and autonomous driving technology. Infrared imaging requires image sensor technology, and InGaAs is almost the only sensing material in the SWIR region.

InGaAs is a III-V group semiconductor and requires expensive deposition methods such as Molecular Beam Epitaxy, and it is difficult to bond InGaAs pixels grown on an InP substrate with similar lattice constants back to a silicon-based integrated circuit. Nevertheless, since there is no alternative material other than the InGaAs-based SWIR image sensor, even though it is an expensive technology, its application is limited to the space, aviation, and military fields.

The Infrared-to-Visible Up-Conversion Device designed to solve this realistic problem is composed of a stack of an infrared sensor and a light-emitting diode (LED), and can convert an infrared image into a visible light image.

The advantage of such an up-conversion image device is that infrared imaging can be easily implemented even with an inexpensive silicon CMOS image sensor. If the up-conversion device is placed in front of the silicon CMOS image sensor, the infrared image is converted to visible light, and the converted visible light image can be detected with a silicon CMOS image sensor.

However, the up-conversion device has a problem of low External Quantum Efficiency (EQE). The external quantum efficiency of the up-conversion device refers to the percentage of the number of visible light photons emitted compared to the number of infrared photons. If the EQE of the infrared detector is about 5%, multiplying the EQE of the LED by 20% gives an EQE of 1%. This means that 100 infrared rays are converted into 1 visible ray.

Low EQE means that high intensity infrared radiation must be irradiated to be converted to visible light and that sensitivity is low. In particular, images may not be visible when used in an environment where infrared light is weak, such as at night or in a foggy environment.

Therefore, in order to commercialize an infrared up-conversion device, it is necessary to have high detectivity and high EQE.

In addition, since the light from the light emitting diode is emitted in all directions like a point light source for each pixel, in order to obtain a clear visible light image from an image sensor, the dispersed light must be focused back onto the image sensor, and this process requires an optical design involving a complex optical system.

This is a factor that must be resolved because it potentially increases the price of up-conversion-based infrared image sensors and causes problems in miniaturizing the product.

U.S. Pat. No. 10,483,325 discloses a structure in which an IR detection thin film and an Organic Light-Emitting Diode (OLED) are inserted into a transistor structure. In the conventional structure, if photocharges generated from infrared rays incident through a two-terminal diode structure are directly transferred to the OELD and emit light, the three-terminal transistor structure is a structure in which infrared rays play the role of changing the capacitance of the gate, greatly increasing the amount of charge transferred to the OLED. Through this, this prior art achieved an EQE of more than 100%.

However, this prior art can produce infrared up-conversion devices with very high EQE, but it consists of a complex structure of more than 10 layers, and there are many factors that increase the price compared to improving device performance, such as the need to design a contact structure according to the three-terminal structure and the need for additional gate power. In practice, this can be a problem when applied to small cameras such as cell phones.

### PRIOR TECHNICAL LITERATURE

### Patent Document

(Patent Document 1) U.S. Pat. No. 10,483,325

### SUMMARY OF THE INVENTION

The present disclosure is created in this technical background, and is structurally simple in up-converting short wavelength infrared light to visible light, and the up-converted light has high straightness, it aims to prevent the optical system from being stretched unnecessarily.

In order to solve the above technical problem, a short wavelength infrared up-conversion device of one embodiment includes a first electrode connected to an anode, an OLED layer stacked on the first electrode and up-converting short-wavelength infrared ray incident through the first electrode into visible light, a blocking layer located between the first electrode and an infrared-sensitive thin film layer to prevent hole injection into the infrared-sensitive thin film layer, an infrared-sensitive thin film layer located between the blocking layer and the OLED layer, and injecting holes into the OLED layer from electron-hole pairs created by absorbing the short-wavelength infrared ray incident through the first electrode, and a transparent second electrode stacked on the OLED layer and connected to a cathode, wherein the first electrode includes a transparent electrode unit, and a reflective electrode unit that reflects visible light incident from the OLED layer to the first electrode toward the second electrode.

The transparent electrode unit may include a first transparent electrode unit located below the reflective electrode unit, and a second transparent electrode unit located above the reflective electrode unit.

The reflective electrode unit may be a metal thin film, and the metal may include silver (Ag), gold (Au), and aluminum (Al).

The transparent electrode unit may be made of metal oxide.

The short wavelength infrared up-conversion device includes a first electrode sequentially stacked in a direction from the first electrode (a reflective electrode unit) to the second electrode, a blocking layer, an infrared-sensitive thin film layer (an infrared-sensitive electron extraction layer and an infrared-sensitive hole injection layer), and an OLED layer stacked on the infrared-sensitive thin film layer. The OLED layer is a device including a hole injection layer, a hole transport layer, an excitation layer, an electron transport layer, an electron injection layer, and a second electrode. To maximize the Microcavity effect, the up-conversion device is configured to satisfy the condition that a combined thickness (d) of the hole blocking layer, the infrared sensitive thin film layer (infrared-sensitive electron extraction layer and infrared-sensitive hole injection layer), the hole injection layer, and the hole transport layer is nd=¼λ (n=refractive index, d=thickness, λ=wavelength).

The short-wavelength infrared up-conversion device according to an embodiment of the present disclosure emits light with linearity rather than dispersed light that spreads out in various directions, so it becomes much easier to focus light onto the image sensor without loss of light. This not only increases the EQE of the up-conversion device by concentrating light emission in one direction, but also simplifies the composition and design of the lens, which is also advantageous when applied to miniaturized products such as cell phones or night vision glasses, and can lower prices through structural simplification.

### BRIEF DESCRIPTION OF THE DRAWINGS

FIG. 1 is a diagram showing an example of a camera to which an up-conversion device is applied according to an embodiment.

FIG. 2 is a diagram showing a layer-by-layer configuration of a first electrode.

FIG. 3 is a diagram showing a detailed configuration of an OLED excluding an electrode.

FIG. 4 is a diagram for explaining an effect of the present disclosure, FIG. 4 (a) shows a light path according to the prior art, and (b) shows a light path according to the present disclosure.

FIGS. 5 and 6 are diagrams for explaining an operation of an up-conversion device.

FIGS. 7 to 11 are diagrams for explaining effects.

### DETAILED DESCRIPTION OF THE EMBODIMENTS

Hereinafter, embodiments of the present disclosure will be described in detail with reference to the drawings. However, detailed descriptions of known functions or configurations that may obscure the gist of the embodiments are omitted in the following description and attached drawings. In addition, throughout the specification, ‘including’ a certain component does not mean excluding other components unless specifically stated to the contrary, but rather means that other components may be further included.

Additionally, terms such as first, second, etc. may be used to describe various components, but the components should not be limited by the above terms.

The above terms may be used for the purpose of distinguishing one component from another component. For example, a first component may be referred to as a second component without departing from the scope of the present disclosure, and similarly, the second component may also be referred to as the first component.

The terms used in the present disclosure are only used to describe specific embodiments and are not intended to limit the present disclosure. Singular expressions include plural expressions unless the context clearly indicates otherwise. In the present disclosure, terms such as “comprise” or “include” are intended to designate the presence of described features, numbers, steps, operations, components, parts, or combinations thereof, and it should be understood that this does not exclude in advance the presence or addition of one or more other features, numbers, steps, operations, components, parts, or combinations thereof.

Unless specifically defined otherwise, all terms used herein, including technical or scientific terms, have the same meaning as generally understood by a person of ordinary skill in the technical field to which the present disclosure pertains. Terms such as those defined in commonly used dictionaries should be interpreted as having a meaning consistent with the meaning in the context of the related technology, and unless clearly defined in the present disclosure, should not be interpreted in an idealized or excessively formal meaning.

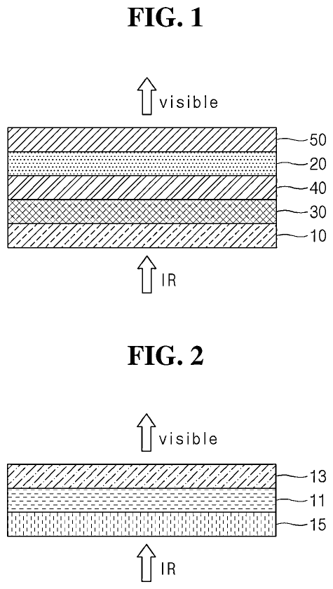

Hereinafter, a short wavelength infrared up-conversion device according to an embodiment of the present disclosure will be described in detail with reference to FIG. 1.

A short wavelength infrared up-conversion device of one embodiment includes a first electrode connected to an anode 10, an OLED layer 20 stacked on the first electrode and up-converting short-wavelength infrared ray incident through the first electrode into visible light, a blocking layer 30 located between the first electrode and an infrared-sensitive thin film layer to prevent hole injection into the infrared-sensitive thin film layer, an infrared-sensitive thin film layer 40 located between the blocking layer and the OLED layer, and injecting holes into the OLED layer from electron-hole pairs created by absorbing the short-wavelength infrared ray incident through the first electrode, and a transparent second electrode 50 stacked on the OLED layer and connected to a cathode, wherein the first electrode 10 includes a transparent electrode unit, and a reflective electrode unit 11 that reflects visible light incident from the OLED layer 20 to the first electrode 10 toward the second electrode 50. In one embodiment, the up-conversion device up-converts short wavelength infrared (IR) incident from the first electrode 10 into visible light and emits it toward the second electrode 50.

As illustrated in FIG. 2, the first electrode 10 is made of a transparent material to transmit short wavelength infrared rays incident on the device from the outside. Additionally, the first electrode 10 reflects some of the visible light emitted toward the first electrode 10 among the visible light up-converted by the OLED layer 20 and directs it toward the second electrode 50. For this purpose, the first electrode 10 includes a semi-permeable material.

Here, the semi-permeable material is a thin film of metal such as silver (Ag), gold (Au), or aluminum (Al). A thin metal film not only transmits part of the incident light, but also reflects part of it.

In one preferred form, the first electrode 10 may be comprised of at least three thin films, as illustrated in FIG. 2. The first electrode 10 includes a reflective electrode unit 11 and transparent electrode units 13 and 15 stacked above and below the reflective electrode unit 11.

Depending on their locations, the transparent electrode units 13 and 15 may include a first transparent electrode unit 13 and a second transparent electrode unit 15. The first transparent electrode unit 13 may be located below the reflective electrode unit 11, and the second transparent electrode unit 15 may be located above the reflective electrode unit 11.

These transparent electrode units 13 and 15 may be made of a transparent conductive material, for example, a metal oxide such as ITO (Indium-Tin-Oxide) or IZO (Indium-Zinc-Oxide).

In the present disclosure, the first electrode 10, which functions as an electrode, not only constitutes an electrode, but is configured so that the light up-converted from the OLED layer 20 is reflected toward the second electrode 50, so the straightness of light is increased and the EQE is improved.

A blocking layer 30 is formed on the first electrode 10 configured in this way.

This blocking layer 30 prevents holes from being injected into the OLED layer 20 through the first electrode 10 connected to the anode, thereby preventing the OLED layer 20 from emitting light. That is, the block layer 30 prevents holes from being injected into the OLED layer 20 in an environment where short wavelength infrared rays are not irradiated, and prevents holes and electrons from recombining in the OLED layer 20 to generate visible light.

This blocking layer 30 is also called Hole Blocking Layer (HBL), and various types of materials have already been developed in the OLED field, and in the present disclosure, without limitation, various types of materials form a blocking layer through a semiconductor process.

The OLED layer 20 is stacked on the blocking layer 30. An excitation layer 21 of this OLED layer 20 emits visible light by recombining holes injected from the first electrode 10 and electrons injected from the second electrode 50. This excitation layer 21 is also called EML (Emission material layer), and various types of materials have already been developed in the OLED field, in the present disclosure, various types of materials without limitation constitute the excitation layer 21 through a semiconductor process.

Meanwhile, an infrared sensitive thin film layer 40 is further formed between the blocking layer 30 and the OLED layer 20, and holes are injected into the OLED layer 20 from electron-hole pairs created by absorbing short wavelength infrared (IR) incident through the first electrode 10.

This infrared-sensitive thin film layer 40 includes quantum dots (QDs) that form electron-hole pairs, and these quantum dots may include at least one of lead sulfide (PbS), lead selenide (PbSe), and indium arsenide (InAs).

Lead sulfide (PbS) used as the infrared sensitive thin film layer 40 is a group IV-VI compound semiconductor, and decreases in size to nanometers, so when the size of semiconductor quantum dots becomes similar to the Bohr diameter of the exciton, as the quantum confinement effect appears, the energy band width of the material gradually increases as the particle size decreases, and the optical properties of the material also change. Therefore, if the size of the lead sulfide (PbS) particle can be adjusted, the energy band width of the particle can also be adjusted, so it can absorb light in the desired wavelength range, that is, short wavelength infrared light.

The second electrode 50 is located above the OLED layer 20, and this second electrode 50 is connected to the cathode. This second electrode 50 is made of a conductive material that transmits light, and is made of various transparent conductive materials without particular limitations.

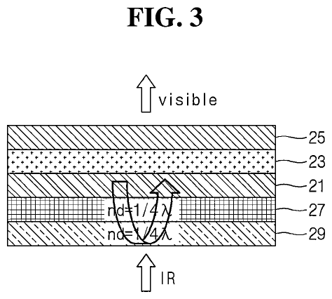

Meanwhile, FIG. 3 shows a detailed configuration of the OLED layer 20.

In FIG. 3. The OLED layer 20 includes an excitation layer 21, a hole injection layer 29, a hole transport layer 27, an electron injection layer 25, and an electron transport layer 23.

The excitation layer (21) is a composition that emits light by recombining electrons and holes, and electrons absorb energy and are temporarily in an excited state, then return to the ground state and emit light. Holes are injected from the anode 10 and electrons are injected from the cathode 50 into the OLED layer 20, at this time, the injection layers 25 and 29 and the transport layers 23 and 27 are respectively arranged sequentially so that electrons and holes are properly transmitted to the excitation layer 21 without being lost between the anode 10 and the excitation layer 21, and the cathode 50 and the excitation layer 21.

In FIG. 3, 29 is a hole injection layer, 27 is a hole transport layer, 25 is an electron injection layer, and 23 is an electron transport layer.

In the present disclosure, when short wavelength infrared (IR) is incident from the first electrode 10, it is up-converted into visible light in the OLED layer 20, and this visible light is emitted in all directions. However, if light is emitted in all directions like this, EQE has no choice but to be lowered. Taking this into consideration, in the present disclosure, the first electrode 10 is configured to further include a reflective electrode unit 11, so that the light radiated toward the first electrode is reflected by the reflective electrode unit 11 and is directed back to the second electrode, so EQE is improved.

In addition, in the present disclosure, the light reflected from the reflective electrode unit 11 is configured to cause constructive interference, thereby maximizing the Microcavity effect. That is, the light emitted from the OLED layer 20 toward the first electrode 10 is reflected from the first electrode 10 and refracted toward the second electrode 50, and it is configured so that the combined thickness of the blocking layer 30, the infrared sensitive thin film layer 40, the hole injection layer 29, and the hole transport layer 27 located on this optical path is ¼ of the wavelength, so constructive interference occurs between lights emitted toward the second electrode. That is, in one embodiment, the combined thickness (d) of the blocking layer 30, the infrared sensitive thin film layer 40, the hole injection layer 29, and the hole transport layer 27 is configured to satisfy the condition of nd=¼λ (n=refractive index, d=thickness, λ=wavelength).

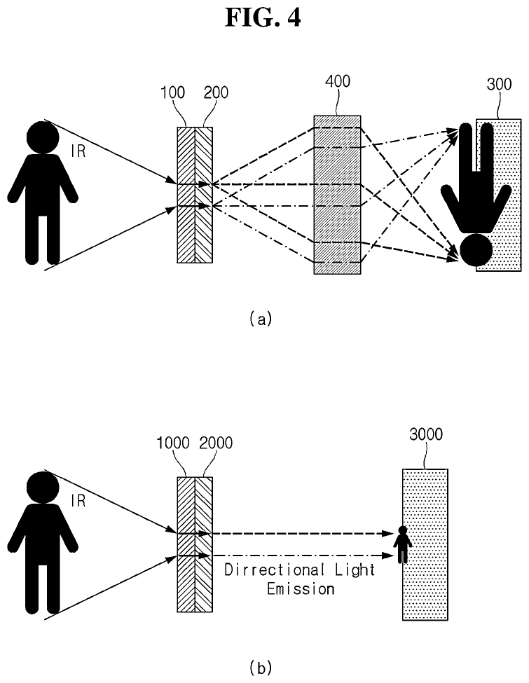

FIG. 4 is a diagram for explaining an effect of the present disclosure. FIG. 4 (a) shows a light path according to the prior art, and (b) shows a light path according to the present disclosure.

As mentioned above, a structure in which an IR detection thin film (or IR sensor, 100) and an OLED 200 are inserted has been disclosed, and the light path in this case is shown in FIG. 4 (a). As shown in (a) of FIG. 4, since the up-converted light from OLED 200 radiates in all directions, the EQE has no choice but to be low, and additionally, in order to form an image on the image sensor 300, a complex optical system 400 must be added.

In contrast, FIG. 4 (b) shows a configuration of an up-conversion device according to the present disclosure, since the light emitted from OLED 2000 is reflected from the first electrode as described above and is strengthened through constructive interference, it has a higher straightness compared to the prior art. Therefore, in order to form an image on the image sensor 3000, a complex optical system is not required as in the prior art, and EQE can also be high due to high straightness.

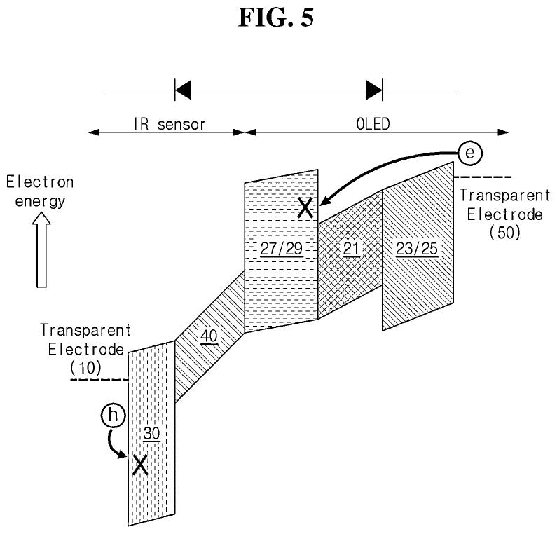

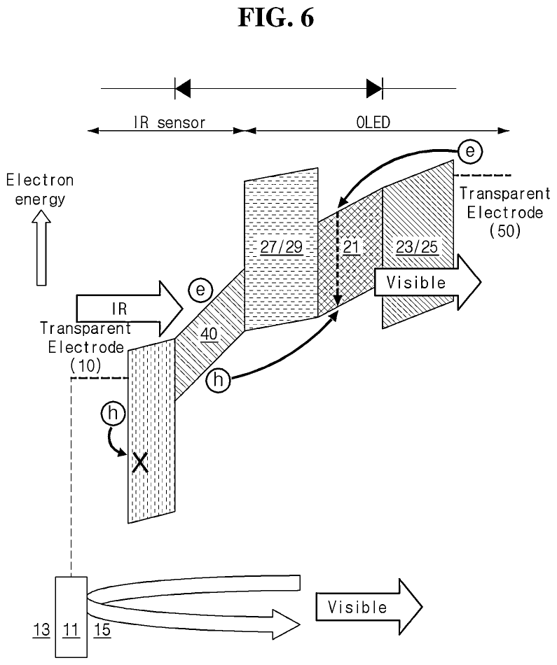

Hereinafter, with reference to FIGS. 5 and 6, operating principle of the up-conversion device according to the present disclosure will be described. FIG. 5 is a diagram illustrating the operation when short wavelength infrared rays are not irradiated, and FIG. 6 is a diagram explaining the operation when short wavelength infrared rays are irradiated.

The up-conversion device has a back-to-back diode structure in which a reverse bias is applied, and OLED is applied with a forward bias.

In an environment where infrared rays are not irradiated, electrons injected from the second electrode 50 cannot recombine with holes in the OLED layer 20, so visible light is not emitted. This is because the blocking layer 30 disposed between the first electrode 10 and the OLED device 20 prevents holes injected through the first electrode 10 from being transmitted to the OLED layer 20.

When short wavelength infrared rays are irradiated to the up-conversion device, the infrared-sensitive thin film layer 40 absorbs short wavelength infrared rays to form electron-hole pairs, and among these, holes move to the OLED layer 20 and meet electrons to emit visible light.

At this time, light is also emitted from the first electrode 10, which means that all light is lost when viewed from the perspective of infrared imaging using an image sensor.

However, in the present disclosure, since the first electrode 10 includes a reflective electrode portion, visible light emitted from the OLED layer toward the first electrode is reflected upward, thereby leading to stronger visible light emission. At this time, the transmittance of short wavelength infrared rays passing through the first electrode 10 is reduced due to the reflective electrode unit of the first electrode 10, which may reduce the amount of light absorbed by the OLED layer 20, but since visible light emission increases due to the Microcavity effect, it is possible to compensate for the loss of light due to the reflective electrode unit.

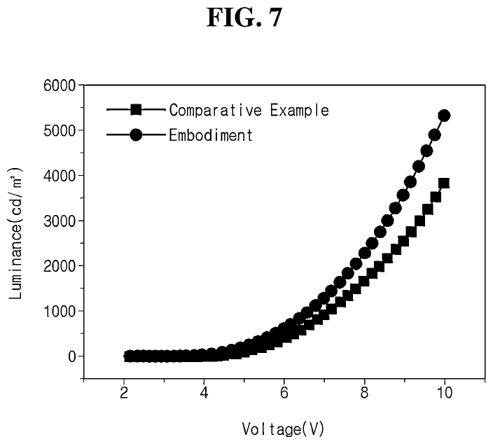

Hereinafter, effects of the present disclosure will be described in more detail with reference to FIGS. 7 to 11.

In the experiment, the first electrode of the Reference OLED (comparative example) is composed of an ITO single layer, and the Microcavity OLED (embodiment) differs only in that the first electrode is composed of ITO/Ag/ITO, and the remaining OLED layers and second electrodes are configured the same.

FIG. 7 shows results of experimenting light emission characteristics of comparative examples and embodiments. The experimental results show that the light emission is stronger in the direction of the second electrode in the case of the embodiment.

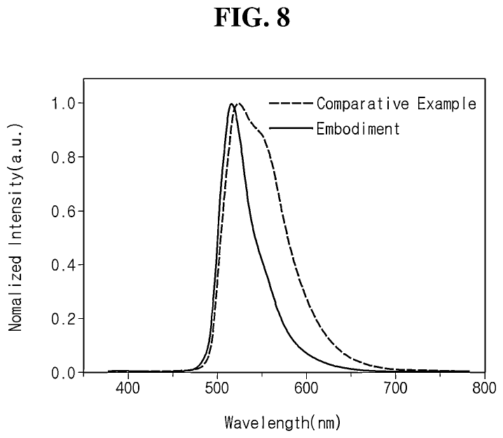

FIG. 8 shows emission spectrum of OLED. It is found that the green light emission absorption spectrum is narrower and light emission with higher color purity is achieved due to the Microcavity effect.

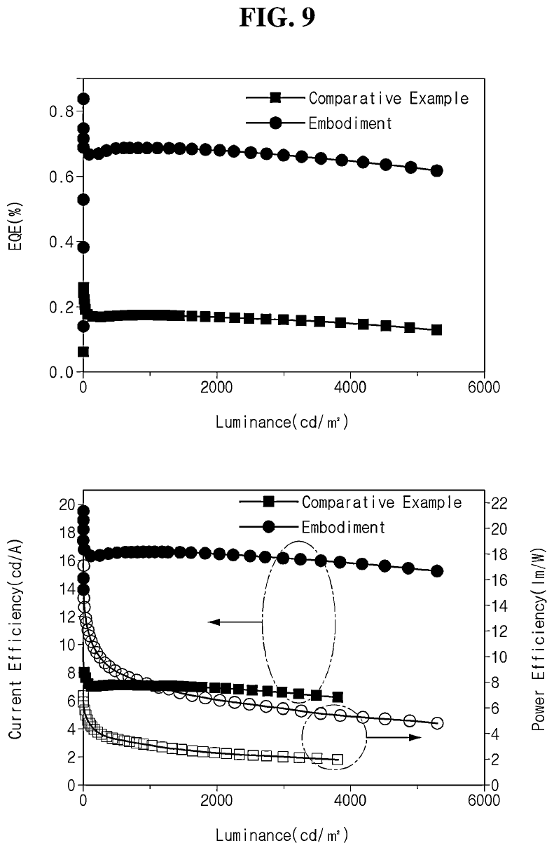

FIG. 9 shows that the external quantum efficiency of light emitted in the direction of the second electrode is higher in the embodiment than in the comparative example due to the Microcavity effect. External quantum efficiency (EQE) indicates how many photons are emitted when 100 electrons are injected. The increased EQE becomes a factor that can increase external quantum efficiency when applying an up-conversion device. In addition, both current efficiency and power efficiency are shown to increase when the Microcavity effect is applied.

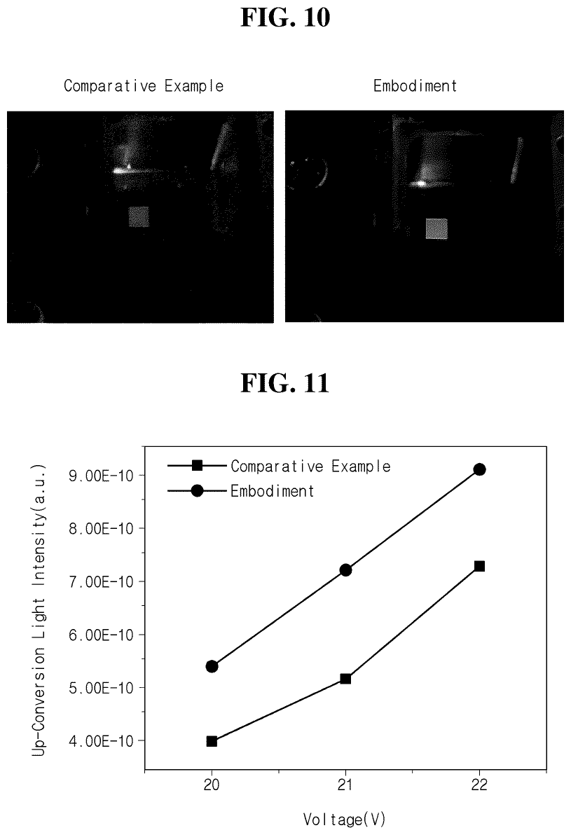

FIGS. 10 and 11 show light emission photographs and light emission intensity of comparative examples and embodiments. When irradiated with the same infrared rays (810 nm) compared to the comparative example the embodiments show stronger visible light emission.

When comparing the light emission intensity compared to the voltage applied to the up-conversion device, an increase in light emission intensity of 1.5 times that of the comparative example is observed in the embodiment.

In the above, the present disclosure has been examined focusing on its various embodiments. Those skilled in the art of the present disclosure will understand that various embodiments may be implemented in modified forms without departing from the essential characteristics of the present disclosure. Therefore, the disclosed embodiments should be considered from an illustrative rather than a restrictive perspective. The scope of the present disclosure is indicated in the claims rather than the foregoing description, and all differences within the equivalent scope should be construed as being included in the present disclosure.

What is claimed is:

1. A short wavelength infrared up-conversion device comprising:
a first electrode connected to an anode;
an OLED layer stacked on the first electrode and up-converting short-wavelength infrared ray incident through the first electrode into visible light;
a blocking layer located between the first electrode and an infrared-sensitive thin film layer to prevent hole injection into the infrared-sensitive thin film layer;
an infrared-sensitive thin film layer located between the blocking layer and the OLED layer, and injecting holes into the OLED layer from electron-hole pairs created by absorbing the short-wavelength infrared ray incident through the first electrode; and
a transparent second electrode stacked on the OLED layer and connected to a cathode,
wherein the first electrode includes
a transparent electrode unit, and
a reflective electrode unit that reflects visible light incident from the OLED layer to the first electrode toward the second electrode.

2. The short wavelength infrared up-conversion device of claim 1, wherein the transparent electrode unit includes a first transparent electrode unit located below the reflective electrode unit, and a second transparent electrode unit located above the reflective electrode unit.

3. The short wavelength infrared up-conversion device of claim 1, wherein the reflective electrode unit is a metal thin film.

4. The short wavelength infrared up-conversion device of claim 3, wherein the metal includes silver (Ag), gold (Au), and aluminum (Al).

5. The short wavelength infrared up-conversion device of claim 1, wherein the transparent electrode unit is made of metal oxide.

6. The short wavelength infrared up-conversion device of claim 1, wherein the up-conversion device includes a hole injection layer and a hole transport layer sequentially stacked in a direction from the first electrode to the second electrode, and
a combined thickness (d) of the blocking layer, the infrared sensitive thin film layer, the hole injection layer, and the hole transport layer is nd=¼λ (n=refractive index, d=thickness, λ=wavelength).

7. The short wavelength infrared up-conversion device of claim 2, wherein the up-conversion device includes a hole injection layer and a hole transport layer sequentially stacked in a direction from the first electrode to the second electrode, and
a combined thickness (d) of the blocking layer, the infrared sensitive thin film layer, the hole injection layer, and the hole transport layer is nd=¼λ (n=refractive index, d=thickness, λ=wavelength).

8. The short wavelength infrared up-conversion device of claim 3, wherein the up-conversion device includes a hole injection layer and a hole transport layer sequentially stacked in a direction from the first electrode to the second electrode, and
a combined thickness (d) of the blocking layer, the infrared sensitive thin film layer, the hole injection layer, and the hole transport layer is nd=¼λ (n=refractive index, d=thickness, λ=wavelength).

9. The short wavelength infrared up-conversion device of claim 4, wherein the up-conversion device includes a hole injection layer and a hole transport layer sequentially stacked in a direction from the first electrode to the second electrode, and
a combined thickness (d) of the blocking layer, the infrared sensitive thin film layer, the hole injection layer, and the hole transport layer is nd=¼λ (n=refractive index, d=thickness, λ=wavelength).

10. The short wavelength infrared up-conversion device of claim 5, wherein the up-conversion device includes a hole injection layer and a hole transport layer sequentially stacked in a direction from the first electrode to the second electrode, and
a combined thickness (d) of the blocking layer, the infrared sensitive thin film layer, the hole injection layer, and the hole transport layer is nd=¼λ (n=refractive index, d=thickness, λ=wavelength).
